(19) United States
(12) Patent Application Publication
(10) Pub. No.: US 2007/0220403 A1
(43) Pub. Date: Sep. 20, 2007

(54) System and method for dynamic allocation of forward error encoding

(75) Inventor: Mark E. Allen, Clearwater, FL (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/363,973

(22) Filed: Feb. 27, 2006

(51) Int. Cl. H03M 13/00

(52) U.S. Cl. 714/774

(57) ABSTRACT

A method for dynamically allocating forward error encoding is disclosed. The method monitors bandwidth utilization for transmitting data, and dynamically adjusts a level of forward error encoding, based on the bandwidth utilization for data, to substantially occupy available bandwidth not being utilized. Also, a communications system is disclosed, which includes a data formatting unit adapted to dynamically adjust the level of forward error encoding based on data bandwidth utilization such that the level of forward error encoding substantially occupies unutilized bandwidth, a transmitter adapted to transmit a data signal formatted by the data formatting unit, and a receiver adapted to receive the transmitted signal containing data and forward error encoding.

### BACKGROUND

In communication systems, noise is often introduced into transmitted signals and corrupts portions of the signal. Virtually all systems are subject to experiencing bit errors. In order to overcome these errors, various forward error correction schemes have been employed. These schemes include both convolutional coding, such as those using the Viterbi algorithm, and block coding, such as Reed-Solomon, Golay, and Hamming error correction codes. Both types add redundancy to the data stream through complex algorithms. In this way, a receiver can detect errors and correct the corrupted bits using the redundant information.

Unfortunately, adding redundancy to the data stream uses up bandwidth. The data is more protected as more redundancy is added, but the increase in redundancy decreases the available bandwidth for transmission of data. Most systems attempt to balance the need for protecting data with the need for increased bandwidth for data by using approximately the minimum amount of coding needed in a worst case scenario for all transmissions. While this approach has historically functioned properly, it is not the most effective use of forward error correction and bandwidth.

### SUMMARY

The above-mentioned problems and other problems are resolved by the present invention and will be understood by reading and studying the following specification.

In accordance with a preferred embodiment of the present invention, a method for dynamically allocating forward error encoding is provided. The method monitors bandwidth utilization for transmitting data, and dynamically adjusts a level of forward error encoding, based on the bandwidth utilization for data, to substantially occupy available bandwidth not being utilized.

In accordance with a second embodiment, a communications system is provided, which includes a data formatting unit adapted to dynamically adjust the level of forward error encoding based on data bandwidth utilization such that the level of forward error encoding substantially occupies unutilized bandwidth, a transmitter adapted to transmit a data signal formatted by the data formatting unit, and a receiver adapted to receive the transmitted signal containing data and forward error encoding.

### DRAWINGS

FIG. 1 is a block diagram of a communication system according to one embodiment of the present invention;

FIG. 2 is a block diagram of a data formatting unit according to one embodiment of the present invention;

FIG. 3 is a block diagram of a forward error encoder according to one embodiment of the present invention; and

FIG. 4 is a flow chart showing a method of dynamically allocating forward error encoding according to one embodiment of the present invention.

Like reference numbers and designations in the various drawings indicate like elements.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the scope of the present invention. It should be understood that the exemplary method illustrated may include additional or fewer steps or may be performed in the context of a larger processing scheme. Furthermore, the methods presented in the drawing figures or the specification are not to be construed as limiting the order in which the individual steps may be performed. The following detailed description is, therefore, not to be taken in a limiting sense.

The present invention enables more effective use of available bandwidth and provides a system and method for improving data protection from bit errors. The present invention accomplishes these functions by dynamically adjusting the level of forward error encoding based on the amount of bandwidth being used for transfer of data. Hence, as less than a maximum amount of bandwidth available is used for data transfer, forward error encoding is increased to substantially fill the available amount of bandwidth.

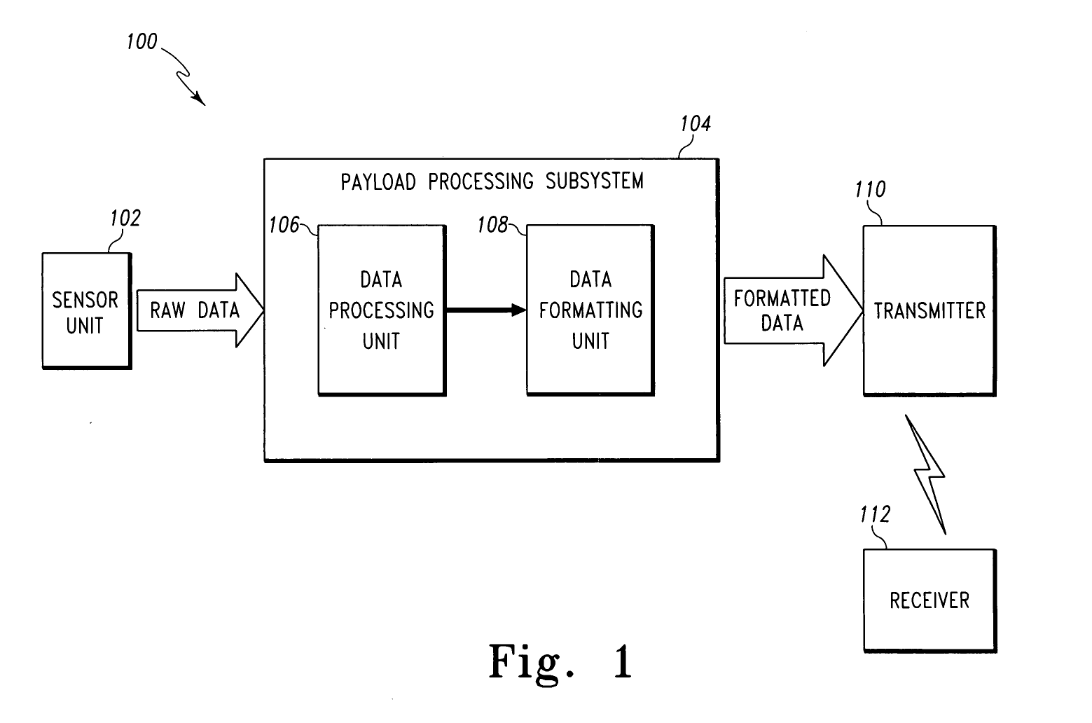

FIG. 1 is a block diagram of a communication system 100 according to one embodiment of the present invention. For this example embodiment, communication system 100 includes a sensor unit 102 coupled to a payload processing subsystem 104. Payload processing subsystem 104 includes a data processing unit 106 adapted to process data received from sensor unit 102, and a data formatting unit 108 coupled to data processing unit 106. Data formatting unit 108 is adapted to format the data for transmission from transmitter 110 to receiver 112. In one example embodiment, data formatting unit 108 and data processing unit 106 are arranged as one physical unit. In a second embodiment, data formatting unit 108 and data processing unit 106 can be arranged as physically separate units that perform their respective functions. In a preferred embodiment, data formatting unit 108, data processing unit 106 and transmitter 110 are located in a spaceborne platform (e.g., satellite, spacecraft, etc.), and receiver 112 is located in a receiving station on Earth.

For this example embodiment, data formatting unit 108 is adapted to monitor the amount of bandwidth being utilized for data. For example, data formatting unit 108 monitors a transmission buffer to determine the amount of bandwidth utilization for data, and adjusts the amount of bandwidth used for forward error encoding based on the amount of bandwidth utilized for data. If data formatting unit 108 determines that the amount of bandwidth being utilized for data is less than a predetermined threshold value, the forward error encoding is increased to utilize the unused bandwidth. In a different embodiment, data formatting unit 108 ensures that a minimum amount of forward error encoding is always used. Data formatting unit 108 is also adapted to format data and forward error encoding for transmission. For example, in a preferred embodiment, data formatting unit 108 is adapted to format data and forward error encoding for transmission in a packet switched network. However, it should be understood that the present invention is not intended to be limited to packet switched networks. For example, data formatting unit 108 can format data and forward error encoding for transmission in circuit switched and cell relay networks.

For this example embodiment, transmitter 110 receives the formatted data containing data and forward error encoding from payload processing subsystem 104, and transmits the formatted data to receiver 112. Preferably, transmitter 110 transmits the formatted data over a wireless radio link. However, it should be understood that the present invention is not intended to be so limited, and transmitter 110 can be adapted to transmit data over other suitable communication media such as, for example, coaxial cable, copper wire, optical fiber, etc. Receiver 112 is adapted to receive the transmitted data and correct any bit errors in the transmitted data using the forward error encoding also received from transmitter 110. In a preferred embodiment, receiver 112 is adapted to automatically detect the level of forward error encoding received. In a different embodiment, the transmitted forward error encoding can include one or more bits indicating to receiver 112 the level of forward error encoding used. Hence, the present invention provides a system that dynamically transfers data with increased error protection, which more effectively uses the available bandwidth.

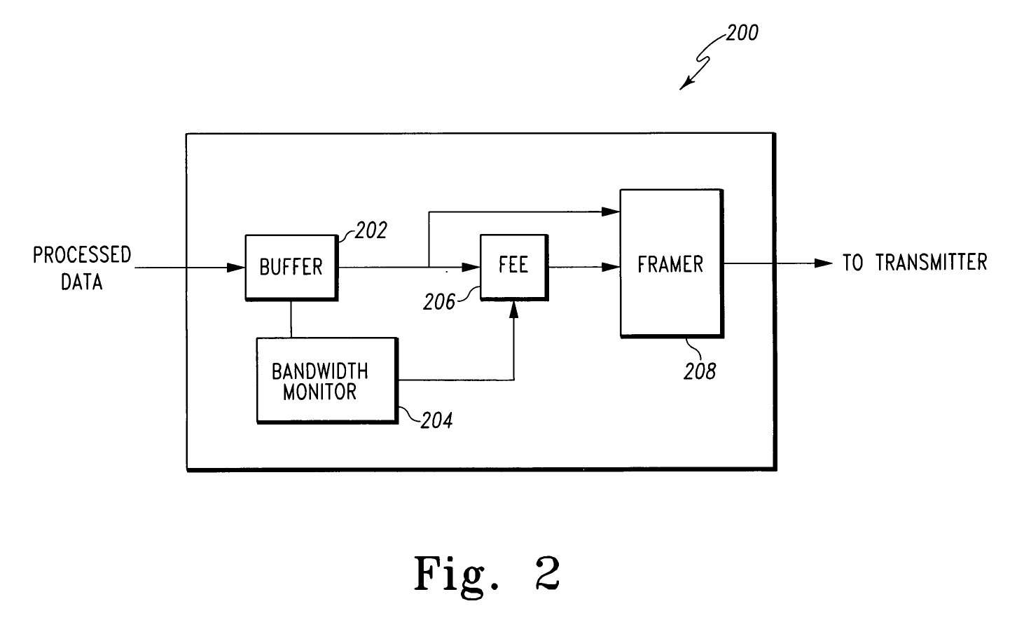

FIG. 2 is a block diagram of a data formatting unit 200, which can be used to implement data formatting unit 108 shown in FIG. 1. For this example embodiment, data formatting unit 200 includes a transmission buffer 202 and bandwidth monitor 204. Bandwidth monitor 204 is coupled to transmission buffer 202 in order to monitor the amount of bandwidth being utilized for data. If the amount of bandwidth being utilized is less than a predetermined threshold value, bandwidth monitor 204 conveys a signal to forward error encoder (FEE) 206, which indicates the level of forward error encoding to be used. In a different embodiment, bandwidth monitor 204 can convey a signal to forward error encoder 206, which indicates whether or not the current amount of bandwidth being utilized for data exceeds a predetermined threshold value. Forward error encoder 206 then determines the level of forward error encoding to be used based on the signal received from bandwidth monitor 204 and the data from buffer 202.

For this example embodiment, framer 208 receives the forward error encoding generated by forward error encoder 206 and the data from buffer 202. Framer 208 formats the data and forward error encoding for transmission over a communication media, such as, for example, a wireless radio link, optical fiber, coaxial cable, etc. In a preferred embodiment, framer 208 formats the data in packets according to a given protocol for transmission by transmitter 110 (e.g., shown in FIG. 1). In a different embodiment, framer 208 can format the data in another suitable format, such as cells in a cell relay network.

In a preferred embodiment, bandwidth monitor 204 is implemented as an application specific integrated circuit (ASIC) adapted to monitor data bandwidth utilization and determine a level of forward error encoding to be used based on data bandwidth utilization. Similarly, forward error encoder 206 can be implemented as an ASIC adapted to determine a level of forward error encoding based on signals received from bandwidth monitor 204.

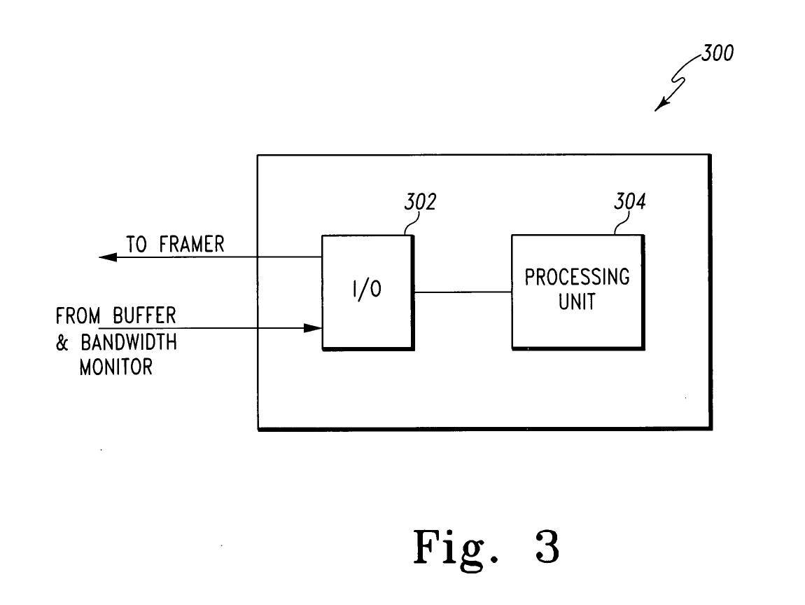

FIG. 3 is a block diagram of a forward error encoder 300, which can be used to implement forward error encoder 206 shown in FIG. 2. For this example embodiment, forward error encoder 300 includes an input/output interface 302, which functions primarily to receive signals from bandwidth monitor 204 and buffer 202 shown in FIG. 2. Forward error encoder 300 also includes at least one processing unit 304, which functions primarily to execute computer-readable code for dynamically adjusting the level of forward error encoding according to signals received from bandwidth monitor 204 in FIG. 2. Processing unit 304 includes interfaces with hardware components and circuitry that support the dynamic allocation of forward error encoding as described above. By way of example and not by way of limitation, these hardware components include one or more microprocessors, memories, storage devices, interface cards, and other standard components known in the art. Additionally, processing unit 304 functions with software programs, firmware or executable computer-readable code for carrying out various methods, process tasks, calculations, control functions, used in the dynamic allocation of forward error encoding as described above. The executable computer-readable code, firmware and software programs are tangibly embodied in any appropriate medium used for storage of computer-readable code including, but not limited to, all forms of non-volatile memory, including, by way of example and not by limitation, semiconductor memory devices, such as EPROM, EEPROM, and flash memory devices; magnetic disks such as internal hard disks and removable disks; magneto-optical disks; and DVD disks. Any of the foregoing may be supplemented by, or incorporated in, specially-designed application-specific integrated circuits (ASICs) and field programmable gate arrays (FPGAs).

For this example embodiment, processing unit 304, through input/output interface 302, receives a signal from buffer 202 and bandwidth monitor 204 (FIG. 2). Processing unit 304 processes the signal from bandwidth monitor 204 according to executable computer-readable code stored on a computer readable medium. In this exemplary embodiment, an executable computer-readable code causes processing unit 304 to select the level of forward error encoding to use based on data bandwidth utilized for data, as indicated by signals received from bandwidth monitor 204, such that the forward error encoding substantially occupies unutilized bandwidth. Processing unit 304 also calculates and generates the forward error encoding data based on the data received from buffer 202 (FIG. 2). Additionally, processing unit 304 selects a default level of forward error encoding when bandwidth utilization for data is greater than a predetermined threshold value. Processing unit 304 then sets the threshold value at a value substantially equal to the maximum amount of bandwidth for data that allows sufficient bandwidth for a minimum level of forward error encoding in a worse case bandwidth scenario. In an alternative embodiment, processing unit 304 does not select a default level of forward error encoding.

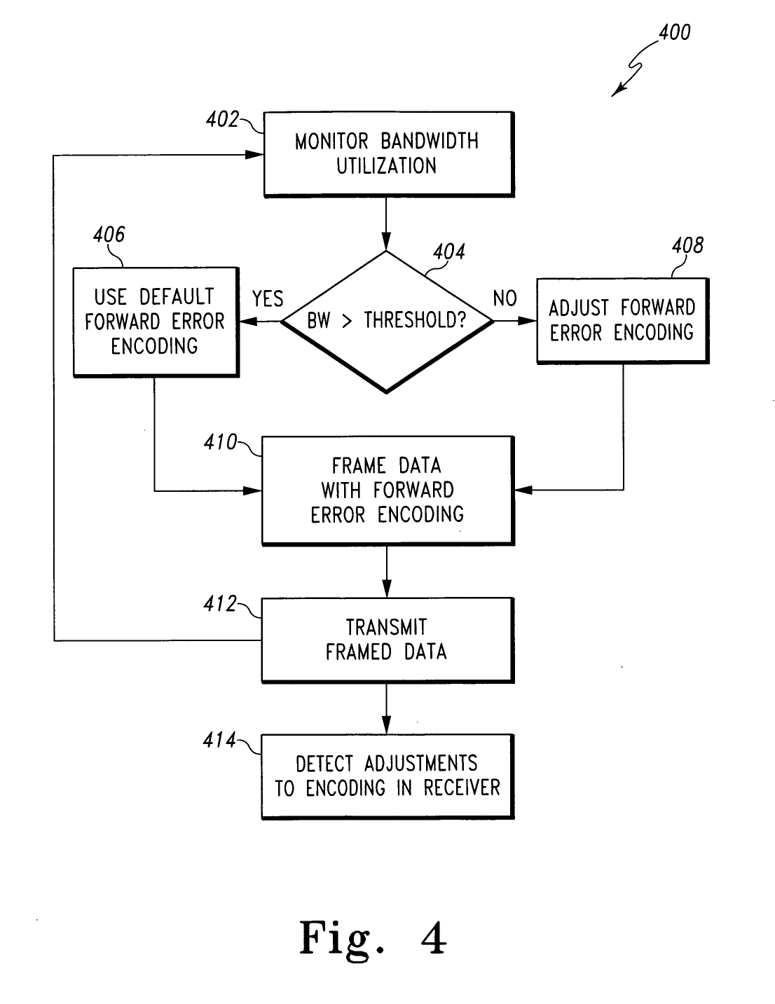

FIG. 4 is a flowchart showing a method 400 of dynamically allocating forward error encoding according to a preferred embodiment of the present invention. At step 402, a data formatting unit (e.g., data formatting unit 108 in FIG. 1), monitors bandwidth utilization. For this example embodiment, a bandwidth monitor (e.g., bandwidth monitor 204 in FIG. 2) in the data formatting unit monitors data in a transmission buffer (e.g., transmission buffer 202 in FIG. 2) to determine the amount of data being transferred at a given time. At step 404, the data formatting unit determines if the bandwidth utilization for data is greater than a predetermined threshold value. For example, the bandwidth monitor determines if the threshold value has been exceeded. If the bandwidth utilization is greater than the threshold value, a forward error encoder (e.g., forward error encoder 206 in FIG. 2), uses a default level of forward error encoding at step 406. For this embodiment, the default level is the minimum level necessary for successful data transmission in a worst case bandwidth scenario. For example, the threshold value is the maximum amount of bandwidth that provides enough bandwidth for the default level of forward error encoding. However, different default levels and threshold values can be used.

If the bandwidth utilization is less than the threshold value, at step 408, the bandwidth monitor indicates to what level the forward error encoder is to adjust the level of forward error encoding such that forward error encoding substantially occupies available bandwidth not being utilized for data. Alternatively, the forward error encoder can determine what level to adjust the forward error encoding. As bandwidth utilization for data increases, the level of forward error encoding decreases and vice versa. For example, if the threshold value is set at the maximum data bandwidth that allows the default level of forward error encoding, then excess unutilized bandwidth between the amount of bandwidth utilized for data and the threshold value is used for forward error encoding.

At step 410, the data formatting unit formats the data and forward error encoding for data transfer. For example, the data formatting unit formats the data in a packet for transfer in a packet-switched network. As another example, the data formatting unit can format the data in another format, such as cells for transfer in a cell relay protocol. At step 412, a transmitter (e.g., transmitter 110 in FIG. 1) transmits the formatted data and forward error encoding to a receiver (e.g., receiver 112). For this example embodiment, the transmitter is adapted to transmit the data over a wireless radio communication link. In an alternative embodiment, the transmitter is adapted to transmit the data over another type of communication medium, such as a wireline, coaxial cable or fiber optic cable. At step 414, a receiver (e.g., receiver 112) receives the transmitted data and detects the adjustments in forward error encoding. In one embodiment, the receiver can detect the adjustments automatically. In a different embodiment, the transmitted forward error encoding contains one or more bits that indicate to the receiver what level of forward error encoding is being used. At step 416, the receiver uses the forward error encoding to correct errors in the data transmitted.

It will be understood by one of skill in the art that the above discussion is related to one cycle of transmitting data and that in practice this cycle repeats quickly and frequently. Additionally, it will be understood by one of skill in the art that one or more method blocks occur substantially simultaneously. For example, in some embodiments, bandwidth monitoring occurs continuously and substantially simultaneously as other steps, such as transmitting formatted data. Additionally, it will be understood by one of skill in the art that in some embodiments, a threshold value and default level of forward error encoding are not used. In such embodiments, the level of forward error encoding is determined based on the bandwidth utilization for data.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed is:

1. A method for dynamically allocating forward error encoding, comprising the steps of:
monitoring a utilization of bandwidth for data to be transmitted; and
adjusting a level of forward error encoding responsive to said utilization of bandwidth, such that bandwidth not being utilized is substantially occupied.

2. The method of claim 1, further comprising the step of:
automatically detecting an adjustment in the level of forward error encoding.

3. The method of claim 1, wherein the monitoring step comprises the step of:
monitoring said data in a transmission buffer.

4. The method of claim 1, wherein the adjusting step further comprises the steps of:
reducing the level of forward error encoding when said utilization of bandwidth increases; and
increasing the level of forward error encoding when said utilization of bandwidth decreases.

5. The method of claim 1, further comprising the step of:
setting a minimum level of forward error encoding to be used.

6. The method of claim 1, further comprising the step of:
setting a minimum level of forward error encoding based on a worst case bandwidth scenario.

7. A communications system, comprising:
a data formatting unit adapted to dynamically adjust the level of forward error encoding based on data bandwidth utilization such that the level of forward error encoding substantially occupies unutilized bandwidth;
a transmitter coupled to said data formatting unit, and adapted to transmit a data signal formatted by the data formatting unit; and
a receiver coupled to said transmitter, and adapted to receive the transmitted signal including said data and forward error encoding.

8. The communications system of claim 7, wherein the transmitter is adapted to transmit signals over a wireless radio link.

9. The communications system of claim 7, wherein the data formatting unit and transmitter are located in a spaceborne platform.

10. The communications system of claim 7, wherein the data formatting unit further comprises:
a buffer adapted to temporarily store data prior to transmission;
a bandwidth monitor coupled to said buffer, and adapted to monitor data in the buffer in order to determine a level of data bandwidth utilization; and
a forward error encoder coupled to the bandwidth monitor and the buffer, the forward error encoder adapted to adjust a level of forward error encoding based on data bandwidth utilization responsive to signals received from the bandwidth monitor.

11. The communications system of claim 10, wherein the forward error encoder comprises an application specific integrated circuit adapted to dynamically adjust forward error encoding based on data bandwidth utilization.

12. The communications system of claim 10, wherein the bandwidth monitor comprises an application specific integrated circuit adapted to determine a level of forward error encoding to be used based on data bandwidth utilization.

13. The communications system of claim 10, wherein the forward error encoder comprises:
an input/output interface adapted to receive a signal from the buffer and bandwidth monitor; and
at least one processing unit coupled to said input/output interface, and adapted to execute software instructions for dynamically adjusting forward error correction levels based on an amount of utilized bandwidth for data.

14. The communications system of claim 10, further comprising:
a framer coupled to said forward error encoder, and adapted to format data and forward error encoding.

15. A computer program product, comprising:
a computer-usable medium having computer-readable code embodied therein for configuring a computer processor, the computer program product comprising:
a first executable computer-readable code configured to cause a computer processor to select a level of forward error encoding based on bandwidth utilized for data such that forward error encoding substantially occupies unutilized bandwidth; and
a second executable computer-readable code configured to cause a computer processor to generate the forward error encoding.

16. The computer program product of claim 15, further comprising:
a third executable computer-readable code configured to cause a computer processor to select a default level of forward error encoding when bandwidth utilized for data is greater than a predetermined threshold value.

17. The computer program product of claim 16, further comprising:
a fourth executable computer-readable code configured to cause a computer processor to set the threshold value at a value substantially equal to the maximum amount of bandwidth for data that allows sufficient bandwidth for a minimum level of forward error encoding in a worse case bandwidth scenario.

18. A communications device, comprising:
means for monitoring data bandwidth utilization;
means for dynamically adjusting forward error encoding, based on the data bandwidth utilization, such that forward error encoding substantially occupies unutilized bandwidth; and
means for transmitting a signal containing the data and forward error encoding.

19. The communications device of claim 18, wherein the means for dynamically adjusting forward error encoding is further adapted to use a default level of forward error encoding when data bandwidth utilization is higher than a given threshold value.

20. The communications device of claim 18, further comprising:
means for formatting the data and forward error encoding for transmission over a communication media.
